(19) United States
(12) Patent Application Publication
(10) Pub. No.: US 2024/0055815 A1
(43) Pub. Date: Feb. 15, 2024

(54) CONNECTION APPARATUS AND RADIO FREQUENCY MODULE

(71) Applicant: HUAWEI TECHNOLOGIES CO., LTD., Shenzhen (CN)

(72) Inventors: Fuhui ZHENG, Dongguan (CN); Wenying ZHANG, Dongguan (CN); Xiaolin ZHOU, Shanghai (CN); Fang CHEN, Shanghai (CN); Yuliang CHONG, Shenzhen (CN); Yuanming MA, Shanghai (CN)

(21) Appl. No.: 18/493,213

(22) Filed: Oct. 24, 2023

Related U.S. Application Data
(63) Continuation of application No. PCT/CN2021/089707, filed on Apr. 25, 2021.

(51) Int. Cl. H01R 24/44; H01R 24/50

(52) U.S. Cl. CPC H01R 24/44; H01R 24/50; H01R 13/03

(57) ABSTRACT

A connection apparatus and a radio frequency module. The connection apparatus includes a conductor assembly and a fastening structure. The fastening structure is configured to fasten the conductor assembly. The conductor assembly includes an outer conductor, an inner conductor, and an insulating elastomer. The inner conductor covers a surface of the insulating elastomer, and the outer conductor and the inner conductor are electrically insulated.

### CROSS-REFERENCE TO RELATED APPLICATIONS

This application is a continuation of International Application No. PCT/CN2021/089707, filed on Apr. 25, 2021, the disclosure of which is hereby incorporated by reference in its entirety.

### BACKGROUND

With the development of wireless communication technologies, miniaturization, integration, and modularization of a wireless base station have become a main development direction of the wireless base station. Generally, the wireless base station includes a plurality of devices such as a transceiver, a filter, and an antenna, and different devices are connected through a connection apparatus, for example, a radio frequency connector.

Currently, based on different device-to-device connection scenarios, the connection apparatus implements a device-to-device connection such as a connection between printed circuit boards (a board-to-board connection), or a connection between a printed circuit board and a filter. The board-to-board connection is used as an example. FIG. 1 and FIG. 2 respectively show schematic structural diagrams of two different connection apparatuses in a conventional technology for implementing the board-to-board connection. As shown in FIG. 1, the connection apparatus includes inner conductor components: an elastic contact pin 1 and an inner core 2. One end of the elastic contact pin 1 is connected to a circuit board 3 in a manner of abutting, the other end of the elastic contact pin 1 is connected to one end of the inner core 2, and the other end of the inner core 2 is connected to another circuit board 3. Therefore, the elastic contact pin 1 and the inner core 2 forms a path between the two circuit boards 3, to implement signal transmission between the two circuit boards 3. As shown in FIG. 2, the connection apparatus includes an insertion end 10, a connecting bar 20, and an import end 30. The insertion end 10 is welded on a circuit board 40, and the import end 30 is welded on another circuit board 40.

However, structures of the foregoing two connection apparatuses are complex and are at high costs. In addition, to ensure that a connection between a device and the connection apparatus is not interrupted in a scenario in which external vibration exists, that is, to ensure high reliability of signal transmission between devices, the foregoing two connection apparatuses each have a specific specified stacking height (stacking height), and therefore cannot be used in a low-stacking-height scenario.

### SUMMARY

Embodiments described herein provide a connection apparatus and a radio frequency module, to meet usage specifications, such as low costs, low stacking height, and high reliability.

According to a first aspect, a connection apparatus is provided. The connection apparatus includes a conductor assembly and a fastening structure. The fastening structure is configured to fasten the conductor assembly. The conductor assembly includes an outer conductor, an inner conductor, and an insulating elastomer. The inner conductor covers a surface of the insulating elastomer, and the outer conductor and the inner conductor are electrically insulated.

Based on the connection apparatus provided in at least one embodiment, the inner conductor and the insulating elastomer are combined to form a connection end. Elastic resilience of the insulating elastomer ensures high reliability of the connection end in resposne to the connection end being configured for connection. In addition, because the insulating elastomer still maintains good elastic resilience in a small size, the insulating elastomer meets a goal of the small size, that is, a usage specification for a low stacking height. Additionally, the connection apparatus has a simple structure and low preparation costs, in other words, meets a low-cost specification.

With reference to the first aspect, in some implementations of the first aspect, the insulating elastomer in a ring-shaped structure, and the inner conductor covers an inner surface of the insulating elastomer.

At least one embodiment provides a structure in which the inner surface of the insulating elastomer is covered with the inner conductor. Because the structure is simple, a simple preparation manner is used in resposne to the structure being prepared, for example, a preparation manner such as performing extrusion molding and cutting on materials of the inner conductor and the insulating elastomer is used. This is easy to prepare and has low preparation costs.

With reference to the first aspect, in some implementations of the first aspect, the inner conductor further covers an end surface of the insulating elastomer.

The connection end is formed by covering the end surface of the insulating elastomer with the inner conductor, so that in resposne to the connection end being configured to connect a device, full contact with the device is ensured, and reliability of signal transmission between devices is further improved.

With reference to the first aspect, in some implementations of the first aspect, the outer conductor covers an outer surface of the insulating elastomer.

At least one embodiment provides a structure in which the outer surface of the insulating elastomer is covered with the outer conductor. Because the structure is simple, a simple preparation manner is used in resposne to the structure being prepared, for example, a preparation manner such as performing extrusion molding and cutting on materials of the outer conductor and the insulating elastomer is used. This is easy to prepare and has low preparation costs.

With reference to the first aspect, in some implementations of the first aspect, the outer conductor further covers the end surface of the insulating elastomer.

The connection end is formed by covering the end surface of the insulating elastomer with the outer conductor, so that in resposne to the connection end being configured to connect a device, full contact with the device is ensured, and reliability of signal transmission between devices is further improved.

With reference to the first aspect, in some implementations of the first aspect, the inner conductor further covers an outer surface of the insulating elastomer. The outer conductor is provided with a through hole, where the inner conductor, the insulating elastomer, and a fastening post are disposed in the through hole.

At least one embodiment provides a structure in which the outer surface of the insulating elastomer is covered with the inner conductor. Because the structure is simple, a simple preparation manner is used in resposne to the structure being prepared, for example, a preparation manner such as performing extrusion molding and cutting on materials of the inner conductor and the insulating elastomer is used. This is easy to prepare and has low preparation costs. Additionally, the inner conductor, the insulating elastomer, and the fastening post are disposed in the through hole of the outer conductor, so that in resposne to the connection apparatus being connected to a device, the outer conductor functions as shielding and isolation and impedance matching, to improve reliability of signal transmission between devices. In addition, the outer conductor is used as a structural component, and is configured to fasten a device in resposne to being connected to the device, to ensure stability of a connection between the devices, and functions as shielding and isolation and impedance matching.

With reference to the first aspect, in some implementations of the first aspect, the fastening structure is a fastening post, and there is an insertion structure between the fastening post and the conductor assembly.

In at least one embodiment, the insertion structure is disposed between the fastening post and the conductor assembly and is simple. This facilitates fastening the fastening post and positioning the conductor assembly. In addition, in resposne to the fastening post and the conductor assembly being in an interference fit (interference fit), stability of a connection between the fastening post and the conductor assembly is further improved.

With reference to the first aspect, in some implementations of the first aspect, the fastening structure is provided with a through hole, and the conductor assembly is disposed in the through hole.

The fastening structure provided with the through hole is used as a structural component. In resposne to the connection apparatus being connected to a device, the fastening structure is configured to fasten the device while fastening and positioning the conductor assembly. This ensures stability of a connection between devices and makes the connection apparatus simple in structure, easy prepare, and low in costs.

With reference to the first aspect, in some implementation of the first aspect, one end of the insulating elastomer is in an arc shape; the inner conductor covers an outer surface of the arc-shaped end of the insulating elastomer; and the outer conductor is provided with a through hole, where the inner conductor, the insulating elastomer and the fastening post are disposed in the through hole.

The one end of the insulating elastomer is set to be arc-shaped, so that in resposne to the arc-shaped end being squeezed, a resilient force of the connection end is reduced, to avoid deformation of the connected structure caused by the resilient force.

With reference to the first aspect, in some implementations of the first aspect, the other end of the insulating elastomer is provided with a hole; the fastening structure is a columnar step-shaped structure; and an insertion structure is formed between the fastening structure and the insulating elastomer through the hole and the columnar step-shaped structure.

The fastening structure is set to be the columnar step-shaped structure. In resposne to a stacking height of the connection apparatus being adjusted, only a height of the fastening structure is adjusted, while heights of structures such as the insulating elastomer and the inner conductor does not need to be adjusted. Therefore, setting the fastening structure to be the columnar step-shaped structure enables the stacking height of the connection apparatus to be easily adjusted.

With reference to the first aspect, in some implementations of the first aspect, the insulating elastomer includes: silicone rubber, nitrile butadiene rubber, or fluorosilicone rubber.

With reference to the first aspect, in some implementations of the first aspect, the inner conductor or the outer conductor includes: silver paste, tin, silver, copper, nickel, or alloy.

According to a second aspect, a radio frequency module is provided, including at least one device and the connection apparatus according to at least one of the foregoing implementations of the first aspect. The device is disposed with an interface. The interface includes an inner conductor connection interface, an outer conductor connection interface, and an insulation area. The insulation area insulates the inner conductor connection interface and the outer conductor connection interface. One end of an inner conductor of the connection apparatus is connected to the inner conductor connection interface, and one end of an outer conductor of the connection apparatus is connected to the outer conductor connection interface.

With reference to the second aspect, in some implementations of the second aspect, the device includes a circuit board or a filter.

### BRIEF DESCRIPTION OF DRAWINGS

FIG. 1 is a schematic structural diagram of a connection apparatus for implementing a board-to-board connection in a conventional technology;

FIG. 2 is a schematic structural diagram of another connection apparatus for implementing a board-to-board connection in a conventional technology;

FIG. 3 is a top view of a device interface according to at least one embodiment;

FIG. 4 is a schematic structural diagram of a specific example of a radio frequency module according to at least one embodiment;

FIG. 5 is a schematic structural diagram of a specific example of a connection apparatus according to at least one embodiment;

FIG. 6 is a schematic structural diagram of a specific example of a radio frequency module according to at least one embodiment;

FIG. 7 is a schematic structural diagram of a specific example of a connection apparatus according to at least one embodiment;

FIG. 8 is a schematic structural diagram of a specific example of a radio frequency module according to at least one embodiment;

FIG. 9 is a schematic structural diagram of a specific example of a connection apparatus according to at least one embodiment;

FIG. 10 is a schematic structural diagram of a specific example of a radio frequency module according to at least one embodiment; and

FIG. 11 is a schematic structural diagram of a specific example of a connection apparatus according to at least one embodiment.

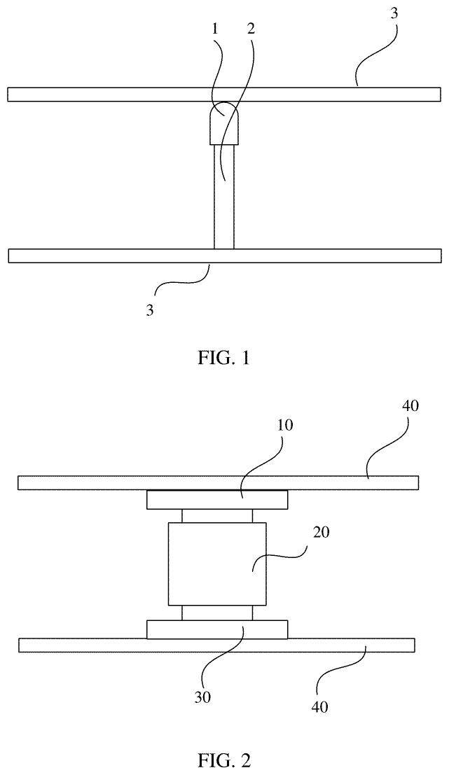

### DESCRIPTION OF EMBODIMENTS

The following describes technical solutions of at least one embodiment with reference to accompanying drawings.

To help a person skilled in the art understand the technical solutions of embodiments described herein, the following first describes a usage scenario of a connection apparatus.

The connection apparatus sometimes is also referred to as a board-to-board connection apparatus or a board-to-board connector, and is mainly configured for interconnection between devices that need to be connected, such as a circuit board, a filter, and an antenna. A radio frequency connector is a common connection apparatus, and is configured to implement a connection between radio frequency devices. For example, in resposne to a connection between printed circuit boards (PCBs), that is, a board-to-board connection being implemented, two connected circuit boards are generally disposed in parallel and are spaced. In other words, the connection apparatus is connected between two circuit boards disposed in parallel, to implement an electrical connection between the circuit boards. Generally, the circuit boards each have electrical connection points such as a first signal end and a second signal end, that is, interfaces. Therefore, the connection apparatus implements a connection between first signal ends of the two circuit boards and a connection between second signal ends of the two circuit boards. In other words, an effective path between the two circuit boards is formed. Similarly, the connection apparatus is configured to implement a connection between devices such as a circuit board and a filter, or is configured to implement a connection between devices such as an antenna and a filter, or is configured to implement a connection and between devices such as filters.

In at least one embodiment, the electrical connection includes all connection manners of connecting different conductive structures.

To connect devices such as a circuit board and a filter that need to be connected, at least one embodiment provides a connection apparatus of low costs, low stacking height, and high reliability.

The connection apparatus provided in at least one embodiment includes a conductor assembly and a fastening structure. The fastening structure is configured to fasten the conductor assembly.

In at least one embodiment, the connection apparatus is disposed between devices to connect the two devices, to implement an electrical connection and signal transmission between the devices.

The devices includes radio frequency devices, for example, radio frequency devices such as a PCB board and a filter that need to be connected. This is not limited in at least one embodiment.

Optionally, one radio frequency module includes at least one radio frequency device, and a connection apparatus that is connected to the device.

The fastening structure is fastened to the device and connected to a part or all of a structure in the conductor assembly, to fasten and position the conductor assembly. Optionally, the fastening structure is further configured to assist the conductor assembly, to implement an electrical connection and signal transmission. A manner of fastening and connecting the fastening structure and the device includes welding, press riveting, injection, or the like. This is not limited in at least one embodiment. In addition, the fastening structure and the part or all of the structure in the conductor assembly is a detachable structure of an interference fit (interference fit), to prevent a corresponding structure in the conductor assembly from falling off.

The fastening structure is made of an insulating material or a conductive medium material. In resposne to the fastening structure being made of the conductive medium material, the fastening structure is configured to assist the conductor assembly to implement the electrical connection and signal transmission between the devices.

The fastening structure is in a plurality of shapes, for example, a columnar shape, a cylindrical shape, or a ring shape. This is not limited in at least one embodiment. For example, in response to the fastening structure being a columnar structure, the fastening structure is connected to part of a through hole structure in the conductor assembly to fasten the part of the through hole structure. In response to the fastening structure being a cylindrical structure or a ring-shaped structure, in other words, the fastening structure is provided with a through hole, the part or all of the structure in the conductor assembly is disposed in the through hole of the fastening structure.

The conductor assembly includes an outer conductor, an inner conductor, and an insulating elastomer. Specifically, the inner conductor is made of a conductive medium material, and covers a surface of the insulating elastomer, to implement signal transmission. The outer conductor is also made of a conductive medium material, and is disposed around an outer side of the inner conductor, that is, disposed on the outer side of the inner conductor and electrically insulated from the inner conductor. In other words, there is a gap between the outer conductor and the inner conductor, and the outer conductor functions as shielding and isolation and impedance matching. The insulating elastomer is made of an electrically insulated non-metallic elastic material with good elastic performance. For example, an insulating elastomer with a compression amount of 20% and a compression set of less than 15% due to long-term aging is considered, to avoid non-rebound after long-term usage and ensure good elastic resilience.

In at least one embodiment, different impedance matching between the inner conductor and the outer conductor is implemented by adjusting structural parameters of the inner conductor and/or the outer conductor, or by adjusting a distance between the inner conductor and the outer conductor.

The conductive medium material for preparing the inner conductor or the outer conductor is any one or more of the following: silver paste, silver, tin, copper, nickel, and alloy. This is not limited in at least one embodiment. The non-metal elastic material for preparing the insulating elastomer is any one or more of the following: silicone rubber, nitrile butadiene rubber, or fluorosilicone rubber. This is not limited in at least one embodiment.

In at least one embodiment, the insulating elastomer is in a solid structure, where a surface of the solid structure is a plane or in an arc shape, for example, a sphere, an ellipsoid, a cylinder, a cube, or a three-dimensional structure of an irregular shape. Alternatively, the insulating elastomer is a three-dimensional structure provided with a through hole, a blind via, or the like. For example, the insulating elastomer is in a ring-shaped structure. The ring-shaped structure is in a circular shape, a square shape, a triangular shape, an irregular shape, and the like. This is not limited in at least one embodiment. For another example, the insulating elastomer is in an arched structure, an inverted U-shaped structure, a cap, and the like. This is not limited in at least one embodiment.

In at least one embodiment, that the inner conductor covers the surface of the insulating elastomer includes: The inner conductor covers part or all of the surface of the insulating elastomer. This is not limited in at least one embodiment. As the material of the inner conductor, the conductive medium material is a material that has good electrical performance and is easy to be combined with the insulating elastomer, for example, various metal coatings such as silver paste.

For a thickness of the inner conductor, an influence of a skin effect of a high-frequency signal is considered, and the thickness of the inner conductor is greater than a skin depth. For example, in resposne to the conductive medium material of the inner conductor being silver paste, and a frequency of a signal transmitted in the inner conductor is 2.6 GHz, a thickness of the silver paste is about 20 μm to 25 μm.

Therefore, a connection end is formed by combining the inner conductor and the insulating elastomer. Based on elastic performance of the insulating elastomer, the connection end has good elastic resilience during compression deformation. This ensures high reliability of the connection end in resposne to the connection end being configured for connection. For example, in resposne to the connection apparatus being configured to connect devices, problems such as assembly tolerance between devices and unevenness and roughness of device surfaces do not affect normal connections and signal transmission between the inner conductor and the devices. In other words, high reliability of the connections is ensured. In addition, because the insulating elastomer still maintains good elastic resilience in a small size, a specification of the small size is met, and a low-stacking-height connection is implemented. In addition, the connection apparatus has a simple structure, is easy to be prepared, and has low preparation costs. This meets a low-cost specification.

Optionally, the connection apparatus further includes a structural component. The structural component is fastened to a device through a fastener. In other words, the structural component is configured to fasten the foregoing device, to ensure stability of a connection between devices. The structural component is another structure different from the conductor assembly and the fastening structure. Alternatively, the structural component is a part of the structure in the conductor assembly, for example, an outer conductor. In other words, the outer conductor implements fastening, shielding and isolation, and impedance matching. Alternatively, the structural component is a fastening structure. In other words, the fastening structure functions as fastening of the conductor assembly and the device.

A manner of covering the surface of the insulating elastomer by the inner conductor and/or the outer conductor is at least one of the following: extrusion molding, electroplating, coating, sputtering, vapor deposition, and pad printing. This is not limited in at least one embodiment.

The following describes the connection apparatus provided in at least one embodiment by using an example in which the connection apparatus is configured to connect two PCB boards disposed in parallel.

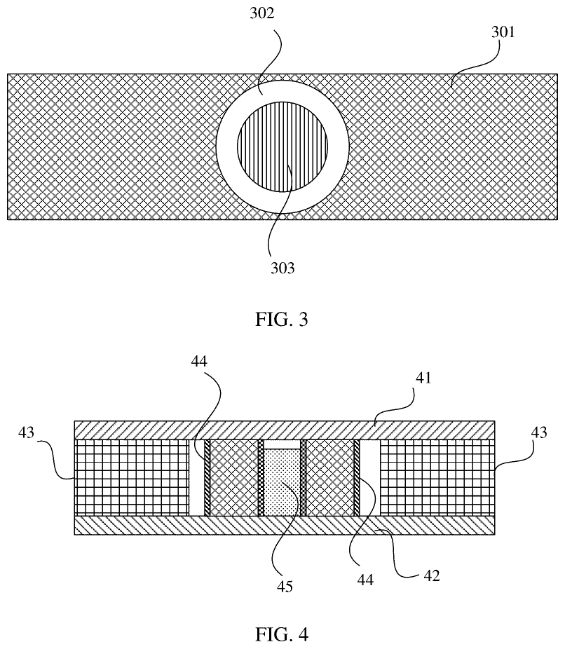

To implement an electrical connection between the PCB board and the connection apparatus, an interface is disposed on a surface of the PCB board. For example, FIG. 3 is a top view of an interface on a PCB board. The interface is used for the electrical connection between the PCB board and the connection apparatus. As shown in FIG. 3, an outer conductor connection interface 301, an insulation area 302, and an inner conductor connection interface 303 are included.

To ensure reliability of a connection between the interface and the connection apparatus, in various scenarios, for example, in a scenario of vibration, size settings of an outer conductor connection interface and an inner conductor connection interface in the interface need to ensure that an electrical connection to a corresponding structure of the connection apparatus is not interrupted. For example, part that is of an inner conductor included in the connection apparatus and that is in contact with the inner conductor connection interface is in a circular shape. This part is referred to as an inner conductor contact part for short. Part that is of an outer conductor included in the connection apparatus and that is in contact with the outer conductor connection interface is in a ring shape. This part is referred to as an outer conductor contact part for short. In addition, in resposne to the inner conductor connection interface and the outer conductor connection interface being in a shape shown in FIG. 3, a diameter of the inner conductor connection interface 303 is greater than a diameter of the circular-shaped inner conductor contact part, and an inner diameter of the outer conductor connection interface 301 is less than an inner diameter of the circular ring-shaped outer conductor contact part, to ensure that the connection between the interface and the connection apparatus is not interrupted.

The interface shown in FIG. 3 is alternatively provided on a device connected to another connection apparatus such as a filter. This is not limited in at least one embodiment.

FIG. 4 shows a schematic structural diagram of a specific example of a radio frequency module according to at least one embodiment.

FIG. 4 shows a sectional view of a radio frequency module. The radio frequency module includes a connection apparatus and upper and lower devices 41 and 42. The connection apparatus includes a conductor assembly 44 and a fastening post 45. Optionally, the connection apparatus further includes a structural component 43.

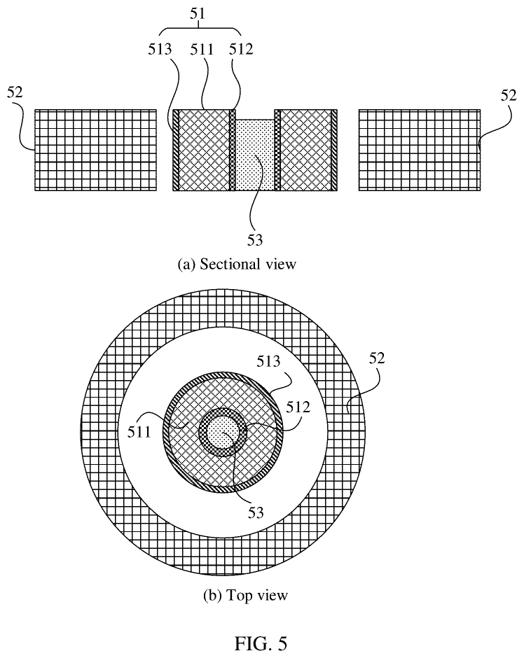

The connection apparatus corresponding to FIG. 4 is described below with reference to FIG. 5. In other words, FIG. 5 shows a schematic structural diagram of a specific example of a connection apparatus according to at least one embodiment.

(a) and (b) in FIG. 5 respectively show a sectional view and a top view of the connection apparatus. The connection apparatus includes a conductor assembly 51 and a fastening post 53. Optionally, the connection apparatus further includes a structural component 52.

The structural component 52 is in a circular ring-shaped columnar structure, and is connected to the upper and lower devices 41 and 42 in FIG. 4 through a fastener such as a screw, a bolt, a stud, or a rivet, that is, a fastener that enables the structural component to be connected and fastened to the devices. This is not limited in at least one embodiment.

The fastening post 53 is in a cylindrical structure, and is fastened to the device 42 in FIG. 4, to function as fastening and positioning of the conductor assembly 51. Optionally, a manner of fastening and connecting the fastening post and the device includes welding, press riveting, injection molding, and the like. This is not limited in at least one embodiment.

Optionally, the fastening post 53 and the conductor assembly 51 are disposed coaxially, and are in an insertion structure. The fastening post and the conductor assembly is in an interference fit. In other words, a diameter of the fastening post 53 is greater than an inner diameter of the conductor assembly 51, to prevent the conductor assembly 51 from falling off.

The following describes a structure of the conductor assembly 51.

In a specific example, the conductor assembly 51 is in a circular ring-shaped columnar structure, and includes an insulating elastomer 511, an inner conductor 512, and an outer conductor 513. The insulating elastomer 511 is in a circular ring-shaped columnar structure, and the inner conductor 512 and the outer conductor 513 respectively cover inner and outer surfaces of the insulating elastomer 511, or in other words, respectively cover inner and outer side surfaces of the insulating elastomer 511.

In resposne to the conductor assembly being configured to connect a device, for example, in resposne to the conductor assembly 51 being connected to the interface shown in FIG. 3, one end of the inner conductor 512 of the conductor assembly 51 is in contact with the inner conductor connection interface 303 of the interface to implement an electrical connection, one end of the outer conductor 513 is in contact with the outer conductor connection interface 301 of the interface to implement an electrical connection, and electrical insulation between the inner conductor and the outer conductor is implemented through the insulating elastomer. In this case, the conductor assembly 51 implements an electrical connection and signal transmission between devices, that is, implement an electrical connection and signal transmission between PCB boards. Optionally, a contact manner between one end of the inner conductor 512 and the inner conductor connection interface 303 is pressing and abutting, and a contact manner between one end of the outer conductor 513 and the outer conductor connection interface 301 is pressing and abutting.

To enable the conductor assembly to be in full contact with the device and improve reliability of signal transmission between devices implemented by the conductor assembly, an outer diameter of one end of the inner conductor 512 of the conductor assembly 51 is set to be less than a diameter of the inner conductor connection interface 303, and an inner diameter of one end of the outer conductor 513 is greater than an inner diameter of the outer conductor connection interface 301.

For a preparation manner of the conductor assembly 51, at least one embodiment is as follows. First, extrusion molding is performed on a non-metal elastic material and a conductive medium layer. Subsequently, cutting is performed to obtain a circular ring-shaped columnar structure with a specific length, for example, a circular ring-shaped columnar structure with a length of about 2 mm. In this case, an inner surface and an outer surface of the circular ring-shaped columnar structure are respectively covered with the conductive medium layers. The conductive medium layer on the inner surface is the inner conductor, and the conductive medium layer on the outer surface is the outer conductor.

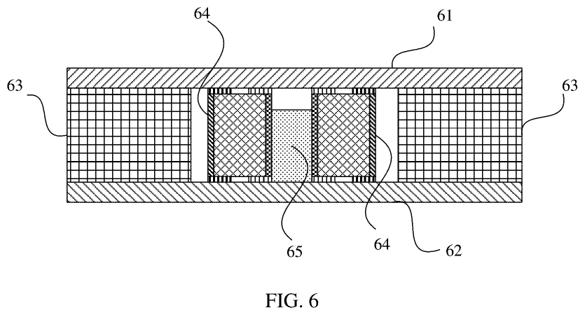

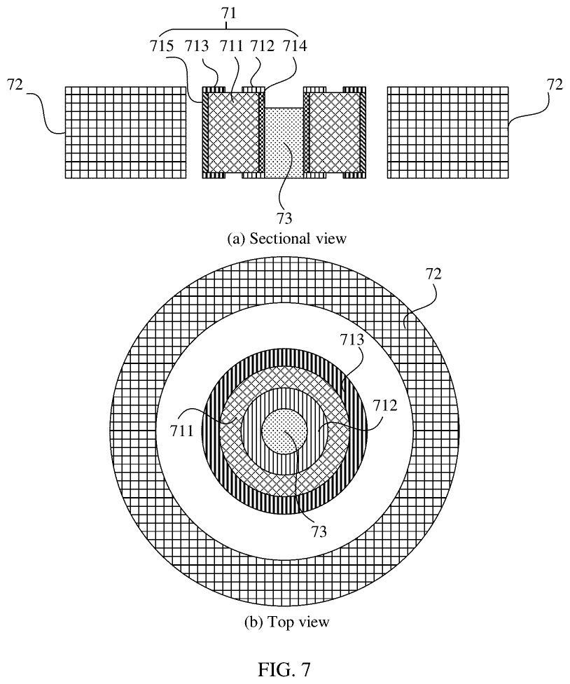

Optionally, as shown in FIG. 6 and FIG. 7, an end surface of the foregoing conductor assembly 51 is alternatively covered with a conductive medium layer, so that the inner conductor and outer conductor of the conductor assembly are in full contact with the inner and outer conductor connection interfaces of the upper and lower devices, to improve reliability of signal transmission between the upper and lower devices implemented by the conductor assembly.

FIG. 6 shows a schematic structural diagram of another specific example of a radio frequency module according to at least one embodiment, and FIG. 7 shows a schematic structural diagram of another specific example of a connection apparatus according to at least one embodiment.

Part of a structure of the radio frequency module shown in FIG. 6 is the same as part of a structure of the radio frequency module shown in FIG. 4, and part of a structure of the connection apparatus shown in FIG. 7 is the same as part of a structure of the connection apparatus shown in FIG. 5. Therefore, for the structures in FIG. 6 and FIG. 7, refer to the descriptions in FIG. 4 and FIG. 5, and details are not described herein again.

FIG. 6 shows a sectional view of the radio frequency module. The radio frequency module includes a connection apparatus and upper and lower devices 61 and 62. The connection apparatus includes a conductor assembly 64 and a fastening post 65. Optionally, the connection apparatus further includes a structural component 63.

The connection apparatus corresponding to FIG. 6 is described below with reference to FIG. 7. In other words, FIG. 7 shows a schematic structural diagram of a specific example of a connection apparatus according to at least one embodiment.

(a) and (b) in FIG. 7 respectively show a sectional view and a top view of the connection apparatus. The connection apparatus includes a conductor assembly 71 and a fastening post 73. Optionally, the connection apparatus further includes a structural component 72.

For descriptions of the structural component 72 and the fastening post 73 in FIG. 7, refer to a specific description of a corresponding structure in FIG. 5. In other words, 52 and 53 are replaced with 72 and 73.

Different from the conductor assembly 51 in FIG. 5, an end of the conductor assembly 71 in FIG. 7 is covered with a conductive medium. In a specific example, the conductor assembly 71 is in a circular ring-shaped columnar structure, and includes an insulating elastomer 711, inner conductors 712 and 714, and outer conductors 713 and 715.

The insulating elastomer 711 is in a circular ring-shaped columnar structure, and the inner conductor and the outer conductor cover a surface of the insulating elastomer. Additionally, the inner conductor further includes the inner conductor 714 on an inner surface and the inner conductor 712 on an end face, and the inner conductor 714 and the inner conductor 712 are electrically connected to each other. The outer conductor further includes the outer conductor 715 on an outer surface and the outer conductor 713 on the end face, and the outer conductor 715 and the outer conductor 713 are also electrically connected to each other. In addition, there is a gap between the inner conductor 712 on the end face and the outer conductor 713 on the end face. In other words, the inner conductor and the outer conductor are electrically insulated.

In resposne to the conductor assembly being configured to connect a device, for example, in resposne to the conductor assembly 71 being connected to the interface shown in FIG. 3, the inner conductor 712 on the end face of the conductor assembly 71 is in contact with the inner conductor connection interface 303 to implement an electrical connection, and the outer conductor 713 on the end face is in contact with the outer conductor connection interface 301 to implement an electrical connection. In this case, the conductor assembly 71 implements an electrical connection and signal transmission between devices, that is, implement an electrical connection and signal transmission between PCB boards. Optionally, a contact manner between the inner conductor 712 on the end face and the inner conductor connection interface 303 is pressing and abutting, and a contact manner between the outer conductor 713 on the end face and the outer conductor connection interface 301 is pressing and abutting.

To enable the conductor assembly to be in full contact with the device and improve reliability of signal transmission between devices implemented by conductor assembly, an outer diameter of the inner conductor 712 on the end face of the conductor assembly 71 is set to be less than a diameter of the inner conductor connection interface 303, and an inner diameter of the outer conductor 713 on the end face of the conductor assembly 71 is set to be greater than an inner diameter of the outer conductor connection interface 301.

For a preparation manner of the conductor assembly 71, at least one embodiment is as follows. First, extrusion molding is performed on a non-metal elastic material and a conductive medium layer. Subsequently, cutting is performed to obtain a circular ring-shaped columnar structure with a specific length, for example, a circular ring-shaped columnar structure with a length of about 2 mm. In this case, an inner surface and an outer surface of the circular ring-shaped columnar structure are respectively covered with the conductive medium layer. The conductive medium layer on the inner surface is an inner conductor, and the conductive medium layer on the outer surface is the outer conductor. Finally, silver paste is coated or printed on the two ends of the structure and then baking is performed, to obtain the inner conductor on the end face and the outer conductor on the end face.

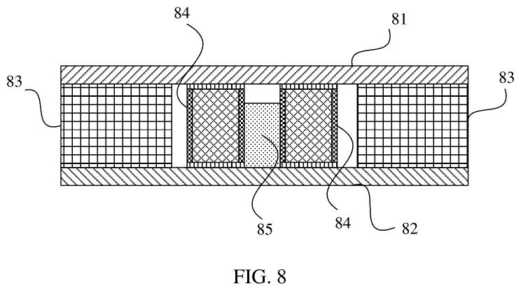

FIG. 8 shows a schematic structural diagram of another specific example of a radio frequency module according to at least one embodiment.

FIG. 8 shows a sectional view of the radio frequency module. The radio frequency module includes a connection apparatus and upper and lower devices 81 and 82. The connection apparatus includes conductor assemblies 83 and 84, and a fastening post 85.

In a specific example, the conductor assembly specifically includes an outer conductor 83 and an inner conductive component 84 formed by an inner conductor and an insulating elastomer. In this case, the outer conductor 83 is also referred to as a structural component. In other words, the outer conductor 83 is configured to fasten the upper and lower devices 81 and 82 in addition to functioning as shielding and isolation and impedance matching. The outer conductor 83 shown in FIG. 8 is in a circular ring-shaped columnar structure. As the structural component, there is a specific distance between the outer conductor 83 and the inner conductive component 84. In other words, the outer conductor is not in contact with the inner conductive component, to ensure electrical insulation between the inner conductor and the outer conductor. In addition, the outer conductor 83 is connected to the upper and lower devices 81 and 82 through a fastener such as a screw, a bolt, a stud, or a rivet, that is, a fastener that enables the outer conductor to be connected and fastened to the devices. This is not limited in at least one embodiment.

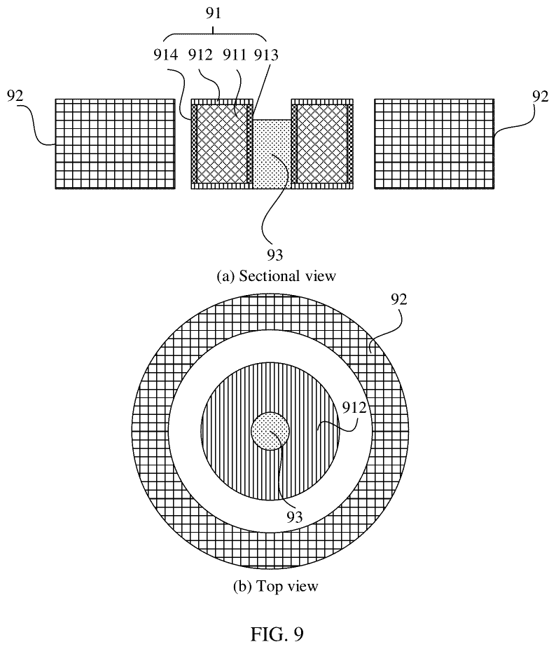

The connection apparatus corresponding to FIG. 8 is described below with reference to FIG. 9. In other words, FIG. 9 shows a schematic structural diagram of a specific example of a connection apparatus according to at least one embodiment.

(a) and (b) in FIG. 9 respectively show a sectional view and a top view of the connection apparatus. The connection apparatus includes a conductor assembly 91, a conductor assembly 92, and a fastening post 93. The conductor assemblies include an outer conductor 92 and an inner conductive component 91 formed by an inner conductor and an insulating elastomer.

The conductor assembly 91 and the conductor assembly 92 are respectively the same as the conductor assembly 84 and the conductor assembly 83 in FIG. 8. For descriptions of the conductor assembly 91 and the conductor assembly 92, refer to related descriptions in FIG. 8.

Optionally, the fastening post 93 is in a cylindrical structure, and is fastened to the device 82 in FIG. 8, to function as fastening and positioning of the inner conductive component 91. Optionally, a manner of fastening and connecting the fastening post and the device includes welding, press riveting, injection molding, and the like. This is not limited in at least one embodiment.

Optionally, the fastening post 93 and the inner conductive component 91 are disposed coaxially, and are in an insertion structure. To prevent the inner conductive component 91 from falling off, the fastening post and the inner conductive component are in an interference fit. In other words, a diameter of the fastening post 93 is greater than an inner diameter of the inner conductive component 91.

The following describes a structure of the inner conductive component 91.

In a specific example, the inner conductive component 91 is in a circular ring-shaped columnar structure, and includes an insulating elastomer 911 and inner conductors 912, 913, and 914. The insulating elastomer 911 is in a circular ring-shaped columnar structure, and the inner conductors 912, 913, and 914 respectively cover an end surface, an inner surface, and an outer surface of the insulating elastomer. In other words, the inner conductor completely covers the insulating elastomer.

In resposne to the conductor assembly being configured to connect a device, for example, in resposne to the outer conductor 92 and the inner conductive component 91 being connected to the interface shown in FIG. 3, the inner conductor 912 included in the inner conductive component 91 is in contact with the inner conductor connection interface 303 to implement an electrical connection, and one end of the outer conductor 92 is in contact with the outer conductor connection interface 301 to implement an electrical connection. In this case, the conductor assembly implements an electrical connection and signal transmission between devices, that is, implement an electrical connection and signal transmission between PCB boards. Optionally, a contact manner between the inner conductor 912 and the inner conductor connection interface 303 is pressing and abutting, and a contact manner between the outer conductor 92 and the outer conductor connection interface 301 is pressing and abutting through a fastener.

To enable the conductor assembly to be in full contact with the device and improve reliability of signal transmission between devices implemented by the conductor assembly, an outer diameter of one end of the inner conductor 912 is set to be less than a diameter of the inner conductor connection interface 303, and an inner diameter of one end of the outer conductor 92 is greater than an inner diameter of the outer conductor connection interface 301.

For a preparation manner of the inner conductive component 91, at least one embodiment is as follows. First, extrusion molding is performed on a non-metal elastic material and a conductive medium layer. Subsequently, cutting is performed to obtain a circular ring-shaped columnar structure with a specific length, for example, a circular ring-shaped columnar structure with a length of about 2 mm. In this case, an inner surface and an outer surface of the circular ring-shaped columnar structure are respectively covered with the conductive medium layers. The conductive medium layers each are an inner conductor. Finally, silver paste is coated or printed on the two ends of the structure and then baking is performed, to obtain an inner conductor on the end surface.

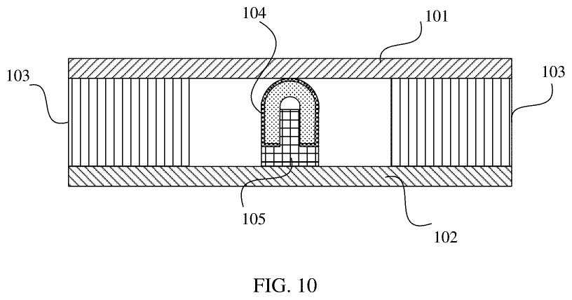

FIG. 10 shows a schematic structural diagram of another specific example of a radio frequency module according to at least one embodiment.

FIG. 10 shows a sectional view of the radio frequency module. The radio frequency module includes a connection apparatus and upper and lower devices 101 and 102. The connection apparatus includes conductor assemblies 103 and 104, and a fastening post 105.

Optionally, the conductor assembly specifically includes an outer conductor 103 and an inner conductive component 104 formed by an inner conductor and an insulating elastomer. In this case, the outer conductor 103 is also referred to as a structural component. In other words, the outer conductor 103 is configured to fasten the upper and lower devices 101 and 102 in addition to functioning as shielding and isolation and impedance matching. The outer conductor 103 shown in FIG. 10 is in a circular ring-shaped columnar structure. As the structural component, there is a specific distance between the outer conductor 103 and the inner conductive component 104. In other words, the outer conductor is not in contact with the inner conductive component, to ensure electrical insulation between the inner conductor and the outer conductor. In addition, the outer conductor 103 is connected to the upper and lower devices 101 and 102 through a fastener such as a screw, a bolt, a stud, or a rivet, that is, a fastener that enables the outer conductor to be connected and fastened to the devices. This is not limited in at least one embodiment.

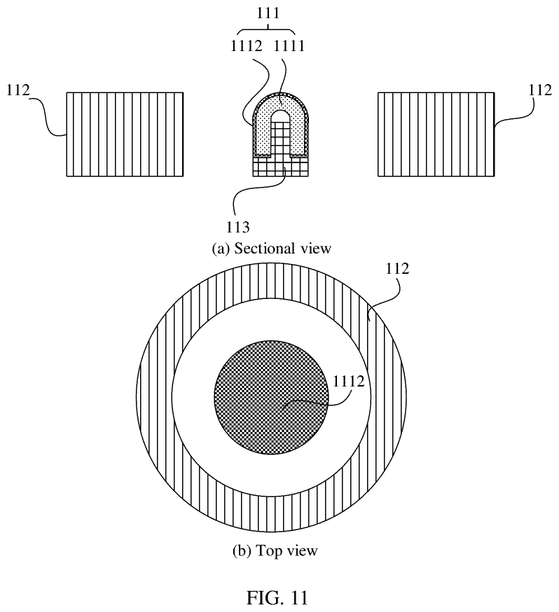

The connection apparatus corresponding to FIG. 10 is described below with reference to FIG. 11. In other words, FIG. 11 shows a schematic structural diagram of a specific example of a connection apparatus according to at least one embodiment.

(a) and (b) in FIG. 11 respectively show a sectional view and a top view of the connection apparatus. The connection apparatus includes a conductor assembly 111, a conductor assembly 112, and a fastening post 113. The conductor assemblies include an outer conductor 112 and an inner conductive component 111 formed by an inner conductor and an insulating elastomer.

The conductor assembly 111 and the conductor assembly 112 are respectively the same as the conductor assembly 104 and the conductor assembly 103 in FIG. 10. For descriptions of the conductor assembly 111 and the conductor assembly 112, refer to related descriptions in FIG. 10.

In a specific example, the fastening post 113 is in a cylindrical step-shaped structure, is connected and fastened to the device 102 in FIG. 10, and functions as fastening and positioning of the inner conductive component 111. Optionally, a manner of fastening and connecting the fastening post and the device includes welding, press riveting, injection molding, and the like. This is not limited in at least one embodiment.

In a specific example, the fastening post 113 and the inner conductive component 111 are coaxially disposed, and are in an insertion structure. To prevent the inner conductive component 111 from falling off, the fastening post and the inner conductive component are in an interference fit. In other words, a diameter of the upper structure of the fastening post 113 is greater than a diameter of a hole of the inner conductive component 111.

The following describes a structure of the inner conductive component 111.

In a specific example, the inner conductive component 111 is in an arch-shaped columnar structure, and includes an insulating elastomer 1111 and an inner conductor 1112. The insulating elastomer 1111 is in an arch-shaped columnar structure with a hole at one end, and the inner conductor 1112 covers an outer surface of the insulating elastomer 1111. Optionally, the inner conductor 1112 further covers an inner surface of the insulating elastomer 1111.

An arch-shaped structure is used on the top of the inner conductive component, so that a rebound force of the inner conductive component caused by compression is reduced. Therefore, in resposne to the inner conductive component being configured to connect a device, deformation of part that is of the device and that is in contact with the inner conductive component is reduced.

Optionally, the inner conductor 1112 is connected to the fastening post 113. In resposne to being configured to connect a device, the fastening post 113 uses a conductive medium, so that the fastening post implements an electrical connection and signal transmission in addition to functioning as fastening and positioning. In addition, the fastening post is in a step shape, which facilitates adjustment of a stacking height. For example, in response to a distance between devices being adjusted, a height of an inner conductive component is not adjusted, and a distance change between devices is adapted by adjusting a height of a fastening post.

In resposne to the conductor assembly being configured to connect a device, for example, in resposne to the outer conductor 112 and the inner conductive component 111 being connected to the interface shown in FIG. 3, the inner conductor 1112 included in the inner conductive component 111 is in contact with the inner conductor connection interface 303 to implement an electrical connection, and one end of the outer conductor 112 is in contact with the outer conductor connection interface 301 to implement an electrical connection. In this case, the conductor assembly implements an electrical connection and signal transmission between devices, that is, implement an electrical connection and signal transmission between PCB boards. Optionally, a contact manner between the inner conductor 1112 and the inner conductor connection interface 303 is pressing and abutting, and a contact manner between the outer conductor 112 and the outer conductor connection interface 301 is pressing and abutting through a fastener.

To enable the conductor assembly to be in full contact with the device and improve reliability of signal transmission between devices implemented by the conductor assembly, an outer diameter of one end of the inner conductor 1112 in the top view in (b) in FIG. 11 is set to be less than a diameter of the inner conductor connection interface 303, and an inner diameter of one end of the outer conductor 112 is greater than an inner diameter of the outer conductor connection interface 301.

For a preparation manner of the inner conductive component 111, at least one embodiment is as follows. First, an insulating elastomer in an arch-shaped structure is prepared by using a non-metal elastic material obtained through compression molding. Subsequently, a conductive medium layer is added to an outer surface of the insulating elastomer through coating or electroplating. The conductive medium layer is the inner conductor.

For ease of description, the radio frequency module in the accompanying drawings of at least one embodiment includes the upper and lower devices connected to the connection apparatus. However, that the radio frequency module necessarily includes two devices connected to the connection apparatus is not limited in at least one embodiment, and there is one or more devices connected to the connection apparatus.

In embodiments described herein, the disclosed systems, apparatuses and methods are understood implemented in another manner. For example, the described apparatus embodiments are merely an example. For example, division of the units is merely logical function division and is other division in actual implementation. For example, a plurality of units or components is combined or integrated into another system, or some features is ignored or not performed. In addition, displayed or discussed mutual couplings or direct couplings or communication connections is implemented through some interfaces. Indirect couplings or communication connections between the apparatuses or units is implemented in electronic or other forms.

The foregoing descriptions are merely specific implementations of at least one embodiment, but are not intended to limit the protection scope of embodiments described herein. Any variation or replacement readily figured out by a person skilled in the art within the technical scope disclosed in at least one embodiment shall fall within the protection scope of embodiments described herein. Therefore, the protection scope of embodiments described herein shall be subject to the protection scope of the claims.

1. A connection apparatus, comprising:
a conductor assembly; and
a fastening structure, wherein the fastening structure is configured to fasten the conductor assembly;
wherein the conductor assembly includes an outer conductor, an inner conductor, and an insulating elastomer, wherein the inner conductor covers a surface of the insulating elastomer, and the outer conductor and the inner conductor are electrically insulated.

2. The connection apparatus according to claim 1, wherein the insulating elastomer is in a ring-shaped structure; and
the inner conductor covers an inner surface of the insulating elastomer.

3. The connection apparatus according to claim 2, wherein the inner conductor further covers an end surface of the insulating elastomer.

4. The connection apparatus according to claim 2, wherein the outer conductor covers an outer surface of the insulating elastomer.

5. The connection apparatus according to claim 4, wherein the outer conductor further covers the end surface of the insulating elastomer.

6. The connection apparatus according to claim 2, wherein the inner conductor further covers an outer surface of the insulating elastomer; and
the outer conductor is provided with a through hole, wherein the inner conductor, the insulating elastomer, and a fastening post are disposed in the through hole.

7. The connection apparatus according to claim 1 wherein the fastening structure includes a fastening post; and
wherein an insertion structure is disposed between the fastening post and the conductor assembly.

8. The connection apparatus according to claim 1, wherein the fastening structure is provided with a through hole, and the conductor assembly is disposed in the through hole.

9. The connection apparatus according to claim 1, wherein one end of the insulating elastomer is in an arc shape;
the inner conductor covers an outer surface of the arc-shaped end of the insulating elastomer; and
the outer conductor is provided with a through hole, wherein the inner conductor, the insulating elastomer, and a fastening post are disposed in the through hole.

10. The connection apparatus according to claim 9, wherein a second end of the insulating elastomer is provided with a hole;
wherien the fastening structure is a columnar step-shaped structure; and
an insertion structure is formed between the fastening structure and the insulating elastomer through the hole and the columnar step-shaped structure.

11. The connection apparatus according to claim 1, wherein the insulating elastomer includes:
silicone rubber, nitrile butadiene rubber, or fluorosilicone rubber.

12. The connection apparatus according to claim 1, wherein the inner conductor or the outer conductor includes:
silver paste, tin, silver, copper, nickel, or alloy.

13. A radio frequency module, comprising:
at least one device, and
at least one connection apparatus, wherein the at least one connection apparatus includes:
a conductor assembly; and
a fastening structure, and wherein the fastening structure is configured to fasten the conductor assembly;
wherien the conductor assembly include an outer conductor, an inner conductor, and an insulating elastomer, wherein the inner conductor covers a surface of the insulating elastomer, and the outer conductor and the inner conductor are electrically insulated;
wherein the device is provided with an interface, wherein the interface includes an inner conductor connection interface, an outer conductor connection interface, and an insulation area, and the insulation area insulates the inner conductor connection interface and the outer conductor connection interface; and
wherein the one end of an inner conductor of the connection apparatus is connected to the inner conductor connection interface, and one end of an outer conductor of the connection apparatus is connected to the outer conductor connection interface.

14. The radio frequency module according to claim 13, wherein the device includes a circuit board or a filter.

15. The radio frequency module according to claim 13, wherein the insulating elastomer is in a ring-shaped structure and the inner conductor covers an inner surface of the insulating elastomer, wherein the inner conductor further covers an end surface of the insulating elastomer and the outer conductor covers an outer surface of the insulating elastomer, and wherein the outer conductor further covers the end surface of the insulating elastomer.

16. The radio frequency module according to claim 13, wherein the inner conductor further covers an outer surface of the insulating elastomer; and
the outer conductor is provided with a through hole, wherein the inner conductor, the insulating elastomer, and a fastening post are disposed in the through hole.

17. The radio frequency module according to claim 13, wherein the fastening structure includes a fastening post; and
wherein an insertion structure is disposed between the fastening post and the conductor assembly.

18. The radio frequency module according to claim 13, wherein the fastening structure is provided with a through hole, and the conductor assembly is disposed in the through hole.

19. The radio frequency module according to claim 13, wherein one end of the insulating elastomer is in an arc shape, the inner conductor covering an outer surface of the arc-shaped end of the insulating elastomer, wherien the outer conductor includes a through hole, wherein the inner conductor, the insulating elastomer, and a fastening post are disposed in the through hole, wherein a second end of the insulating elastomer is provided with a hole and the fastening structure is a columnar step-shaped structure, wherein an insertion structure is formed between the fastening structure and the insulating elastomer through the hole and the columnar step-shaped structure.

20. The radio frequency module according to claim 13, wherein the insulating elastomer includes silicone rubber, nitrile butadiene rubber, or fluorosilicone rubber, and wherein the inner conductor or the outer conductor includes silver paste, tin, silver, copper, nickel, or alloy.
